(19) United States
(12) Patent Application Publication
(10) Pub. No.: US 2020/0161353 A1
(43) Pub. Date: May 21, 2020

(54) IMAGE SENSOR, MANUFACTURING METHOD THEREOF AND IMAGING DEVICE

(71) Applicant: HUAIAN IMAGING DEVICE MANUFACTURER CORPORATION, HUAIAN (CN)

(72) Inventors: Yangyang WANG, HUAIAN (CN); Maoliang TANG, HUAIAN (CN); Shaodong LIU, HUAIAN (CN)

(73) Assignee: HUAIAN IMAGING DEVICE MANUFACTURER CORPORATION, HUAIAN (CN)

(21) Appl. No.: 16/570,568

(22) Filed: Sep. 13, 2019

(30) Foreign Application Priority Data
Nov. 20, 2018 (CN) 201811379519.X

(51) Int. Cl. H01L 27/146

(52) U.S. Cl. CPC H01L 27/14623; H01L 27/14603; H01L 27/1463; H01L 27/14621; H01L 27/14627; H01L 27/14643; H01L 27/14685

(57) ABSTRACT

An image sensor comprising a substrate, a black pixel area formed in the substrate including a black pixel radiation sensing element. an active pixel area formed in the substrate, and a buffer area, wherein the black pixel area and the active pixel area sandwich the buffer area in a transverse direction of the substrate, and a first blocking wall that at least partially blocks the radiation propagating towards the black pixel radiation sensing element via the buffer area in the substrate is formed in the buffer area.

### CROSS-REFERENCE TO RELATED APPLICATIONS

This application claims priority to Chinese Patent Application No. 201811379519.X, filed on Nov. 20, 2018, which is hereby incorporated by reference in its entirety.

### TECHNICAL FIELD

The present disclosure relates generally to the field of semiconductor technology, and more particularly, to an image sensor, a manufacturing method thereof and an imaging device.

### BACKGROUND

Image sensors can be used to sense radiation (e.g., light radiation, including but not limited to visible light, infrared ray, ultraviolet ray, X-ray, etc.) to generate corresponding electrical signals (e.g., images). It is widely used in digital cameras, mobile communication terminals, security facilities and other imaging devices.

In image sensors (such as CMOS image sensor (CIS) products), the dark current is inevitable and is a major performance parameter. In order to detect radiation accurately, a black pixel radiation sensing element is provided in the image sensor to measure the magnitude of the dark current, so as to remove the influence of the dark current on the image sensor as much as possible. However, in the prior art, the black pixel radiation sensing element may be affected by the stray radiation from the outside of the image sensor, which will interfere with the measurement of the dark current. In addition, the active pixel radiation sensing element in the image sensor may also be affected by the external stray radiation.

Therefore, it is necessary to propose new technologies to solve one or more of the problems in the prior art as mentioned above.

### SUMMARY

One aspect of this disclosure is to provide an image sensor comprising: a substrate; a black pixel area formed in the substrate including a black pixel radiation sensing element; an active pixel area formed in the substrate; and a buffer area, wherein the black pixel area and the active pixel area sandwich the buffer area in a transverse direction of the substrate, and a first blocking wall that at least partially blocks the radiation propagating towards the black pixel radiation sensing element via the buffer area in the substrate is formed in the buffer area.

Another aspect of this disclosure is to provide a method for manufacturing an image sensor comprising: providing a substrate; forming a black pixel area and an active pixel area in the substrate, wherein a buffer area is sandwiched between the black pixel area and the active pixel area in a transverse direction of the substrate; forming a black pixel radiation sensing element in the black pixel area; and forming a first blocking wall in the buffer area, which at least partially blocks the radiation propagating towards the black pixel radiation sensing element via the buffer area in the substrate.

Yet another aspect of this disclosure is to provide an imaging device comprising: the image sensor as described above; and a lens for converging the external radiation and guiding it to the image sensor.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 is a schematic diagram showing the distribution of the pixel areas of an image sensor in the prior art.

FIG. 2 is a schematic cross-sectional view showing an image sensor of the prior art.

FIG. 3 is a schematic cross-sectional view showing an image sensor of the prior art, which shows the adverse effects of the radiation from the external of the image sensor on a black pixel radiation sensing element.

FIG. 4 is a schematic cross-sectional view showing an image sensor of the prior art, which shows the adverse effects of the radiation from the external of the image sensor on an active pixel radiation sensing element.

FIG. 5 is a schematic cross-sectional view showing an image sensor in some embodiments of the present disclosure.

FIG. 6 is a schematic cross-sectional view showing an image sensor in some embodiments of the present disclosure.

FIG. 7 is a schematic cross-sectional view showing an image sensor in some embodiments of the present disclosure.

FIG. 8 is a schematic cross-sectional view showing an image sensor in some embodiments of the present disclosure.

FIG. 9 is a schematic cross-sectional view showing an image sensor in some embodiments of the present disclosure.

FIG. 10 is a schematic cross-sectional view showing an image sensor in some embodiments of the present disclosure.

FIG. 11 is a flowchart illustrating a manufacturing method of an image sensor in some embodiments of the present disclosure.

FIG. 12 is a schematic cross-sectional view showing an image sensor corresponding to some steps of the manufacturing method shown in FIG. 11.

FIG. 13 is a schematic cross-sectional view showing an image sensor corresponding to some steps of the manufacturing method shown in FIG. 11.

FIG. 14 is a schematic cross-sectional view showing an image sensor corresponding to some steps of the manufacturing method shown in FIG. 11.

FIG. 15 is a schematic cross-sectional view showing an image sensor corresponding to some steps of the manufacturing method shown in FIG. 11.

FIG. 16 is a schematic cross-sectional view showing an image sensor corresponding to some steps of the manufacturing method shown in FIG. 11.

FIG. 17 is a schematic cross-sectional view showing an image sensor corresponding to some steps of the manufacturing method shown in FIG. 11.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In the image sensor, besides the active pixel radiation sensing element, the black pixel radiation sensing element may also be provided to measure the magnitude of the dark current. The black pixel radiation sensing element may be a sensing element that is the same as the active pixel radiation sensing element, but the black pixel radiation sensing element is shielded or masked by an opaque component or material layer so as to avoid receiving the radiation from the outside of the image sensor.

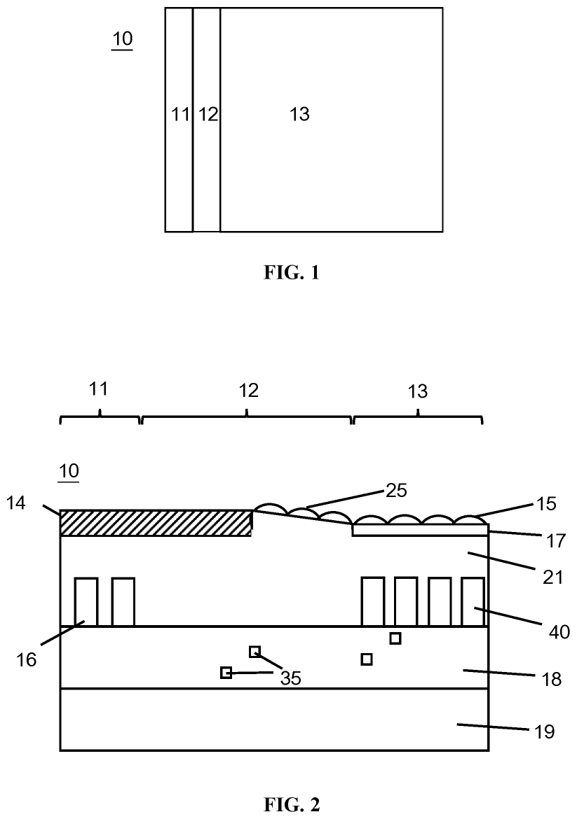

FIG. 1 is a schematic diagram showing the distribution of the pixel areas in the image sensor 10 of the prior art. FIG. 2 is a schematic cross-sectional view showing the image sensor 10 of the prior art.

As shown in FIG. 1, the pixel areas of the image sensor 10 are divided into a black pixel area 11 and an active pixel area 13. Between the black pixel area 11 and the active pixel area 13, a buffer area 12 is provided.

As shown in FIG. 2, one or more black pixel radiation sensing elements 16 may be formed in the black pixel area 11, and one or more active pixel radiation sensing elements 40 may be formed in the active pixel area 13. The black pixel radiation sensing element 16 is used to sense the magnitude of the dark current in the substrate 21 of the image sensor. The active pixel radiation sensing element 40 is used to sense radiation from the outside of the image sensor to form, for example, an image signal.

At the upper end of FIG. 2, a schematic distribution range of a black pixel area 11, a buffer area 12 and an active pixel area 13 corresponding to FIG. 1 is shown. However, in order to facilitate the description, the range of the buffer area 12 in FIG. 2 is shown to be relatively large. The purpose for providing the buffer area 12 is to isolate the black pixel area 11 and the active pixel area 13 so as to reduce the signal crosstalk caused by the active pixel area 13 to the black pixel area 11, thereby improving the sensing accuracy of the black pixel radiation sensing element 16.

In addition, shielding metal 14 is provided above the black pixel radiation sensing element 16 so as to shield the radiation from the outside.

Above the active pixel radiation sensing element 40, a color filter 17 for filtering the radiation incident on the image sensor and one or more microlenses 15 for converging the radiation to cause the radiation to propagate to the active pixel radiation sensing elements 40 may be provided. In addition, in the buffer area 12, a pseudo microlens 25 may be provided. There is no active pixel radiation sensing element below the pseudo-microlens 25, so the pseudo microlens 25 is not actually used for image sensing.

In addition, under the substrate 21, a dielectric stack 18 may be provided. In the dielectric stack 18, metal interconnections 35 may be formed. The carrier wafer 19 may be provided under the dielectric stack 18.

However, in the prior art, the black pixel radiation sensing element 16 will be affected by the stray radiation from the outside of the image sensor 10, which will interfere with the measurement of the dark current. This is described in more detail below.

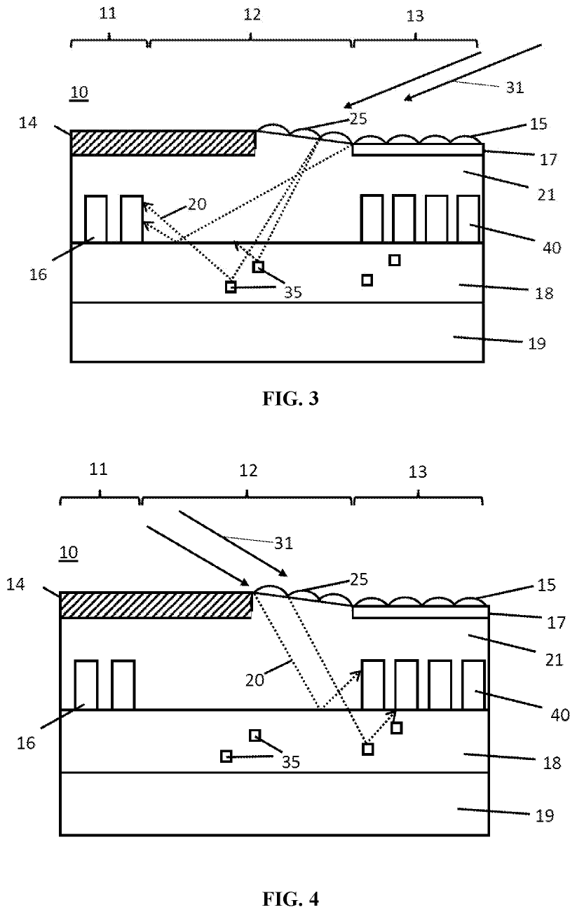

FIG. 3 is a schematic cross-sectional view showing the image sensor 10 of the prior art, which shows the adverse effects of the radiation 31 from the outside of the image sensor on the black pixel radiation sensing element 16. As shown in FIG. 3, after passing through the pseudo-microlens 25, a part of the radiation 31 from the outside may be reflected by the dielectric stack 18 and the metal interconnections 35 in the dielectric stack 18. The reflected radiation (for example, the stray radiation 20 shown by dashed lines in the figure) may propagate to and be sensed by the black pixel radiation sensing element 16. In addition to the above radiation, there may be other radiation propagating via the buffer area 12 of the substrate 21 to the black pixel radiation sensing element 16. All these radiations absorbed by the black pixel radiation sensing element 16 may affect the accuracy of its measurement of the dark current.

The stray radiation 20 may affect not only the black pixel radiation sensing element 16, but also the active pixel radiation sensing element 40, as shown in FIG. 4. As shown in FIG. 4, after passing through the pseudo-microlens 25, a part of the radiation 31 from the outside may be reflected by the dielectric stack 18 and the metal interconnections 35 in the dielectric stack 18, and the reflected radiation (for example, the stray radiation 20 shown by dashed lines in the figure) may propagate to and be sensed by the active pixel radiation sensing element 40. In addition to the above radiation, there may be other radiation propagating via the buffer area 12 of the substrate 21 to the active pixel radiation sensing element 40. All these radiations absorbed by the active pixel radiation sensing element 40 may affect its sensing of the image.

In order to improve one or more of the above technical problems existing in the prior art, the inventor of the present application proposes a new technical concept: setting a blocking wall in the buffer area so as to at least partially block the radiation propagating via the buffer area to the black pixel radiation sensing element.

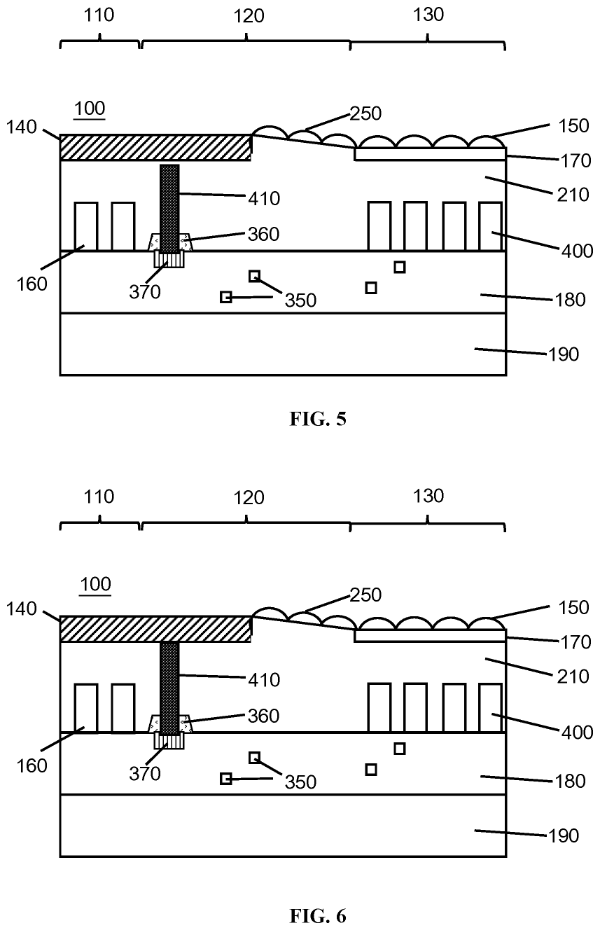

FIG. 5 is a schematic cross-sectional view showing an image sensor 100 in some embodiments of the present disclosure. As shown in FIG. 5, the image sensor 100 includes a substrate 210. The substrate 210 may be composed of suitable one-component semiconductor materials (such as silicon or germanium) or compound semiconductors (such as silicon carbide, silicon germanium, gallium arsenide, gallium phosphide, indium phosphide, indium arsenide and/or indium antimonide) or combinations thereof. In addition, for example, the substrate 210 may use SOI (silicon on insulators) substrate or any other suitable material. The substrate 210 may have a first main surface and an opposite second main surface.

An active pixel area 130 and a black pixel area 110 are formed in the substrate 210, and a black pixel radiation sensing element 160 (e.g., an optical sensing element (e.g., a photodiode) is formed in the black pixel area 110. In the transverse direction of the substrate 210, the active pixel area 130 and the black pixel area 110 sandwich the buffer area 120. At the upper end of FIG. 5, a schematic distribution range of the black pixel area 110, the buffer area 120 and the active pixel area 130 are shown. The purpose of providing the buffer area 120 is to isolate the black pixel area 110 and the active pixel area 130, so as to reduce the signal crosstalk caused by the active pixel area 130 to the black pixel area 110, thereby improving the sensing accuracy of the black pixel radiation sensing element 160.

In the buffer area 120, a blocking wall 410 is formed. The blocking wall 410 can at least partially block the radiation propagating towards the black pixel radiation sensing element 160 in substrate 210 via the buffer area 120, thereby can reduce the influence of the external radiation on the black pixel radiation sensing element 160. The materials for forming the blocking wall 410 may be opaque, translucent or radiation absorbing materials.

In some embodiments, the opaque material or translucent material may be any suitable material, such as metal, resin, plastics, metallic or non-metallic oxides, graphite, etc., or the combination of these materials. In some embodiments, the radiation absorbing material may be germanium or silicon germanium, for example. In some embodiments, the opaque material may be tungsten.

In FIG. 5, the blocking wall 410 is schematically illustrated as perpendicular to the main surface of the substrate 210. However, the blocking wall 410 may extend obliquely relative to the main surface of the substrate 210 rather than being perpendicular to the main surface of the substrate 210. In some embodiments, the blocking wall 410 may also be in a fold line shape or curved shape or any other suitable shape in, for example, the cross-sectional view shown in FIG. 5 of the image sensor, provided that the radiation propagating in the substrate 210 towards the black pixel radiation sensing element 160 via the buffer area 120 can be at least partially blocked.

In some embodiments, a shielding area 140 may be set above the black pixel radiation sensing element 160 to block at least partially the radiation propagating towards the black pixel radiation sensing element 160 from above the black pixel radiation sensing element 160. The shielding area 140 is formed of opaque material, which may be any suitable material, such as metal, resin, plastic, metallic or non-metallic oxide, graphite, etc., or a combination of these materials. In some embodiments, the opaque material may be aluminium.

In FIG. 5, the shielding area 140 is schematically illustrated as being located on the upper surface of the substrate 210. However, the shielding area 140 may be located in the substrate 210, as long as it is above the black pixel radiation sensing element 160 so as to at least partially block the radiation propagating towards the black pixel radiation sensing element 160 from above the black pixel radiation sensing element 160.

In some embodiments, as shown in FIG. 5, the shielding area 140 extends from the black pixel area 110 to the buffer area 120 and occupies at least a part of the buffer area 120. In this case, the blocking wall 410 and the shielding area 140 together can block most of the radiation propagating via the buffer area 120 towards the black pixel radiation sensing element 160.

In some embodiments, as shown in FIG. 6, a portion of the blocking wall 410 may be in contact with the shielding area 140, thereby further reducing the radiation propagating towards the black pixel radiation sensing element 160 from the gap between the blocking wall 410 and the shielding area 140.

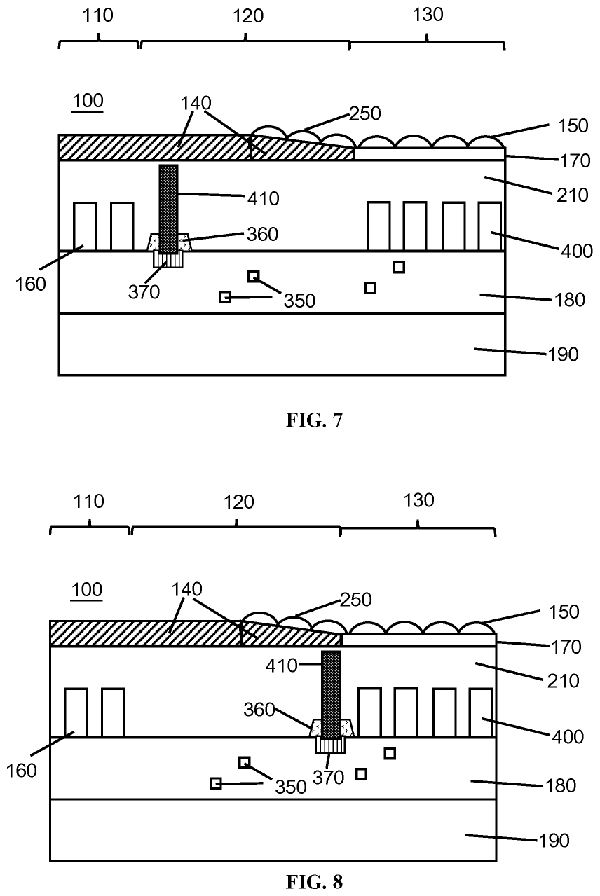

In some embodiments, as shown in FIG. 7, the shielding area 140 may span cross the entire black pixel area 110 and the entire buffer area 120 in a transverse direction, thereby blocking the radiation incident from above the entire black pixel area 110 and the entire buffer area 120.

In some embodiments, the active pixel area 130 includes an active pixel radiation sensing element 400. In some embodiments, as shown in FIG. 8, the blocking wall 410 may be formed at a position adjacent to the active pixel area 130 in the buffer area 120. In this case, the blocking wall 410 not only can block at least partially the radiation propagating in the substrate 210 towards the black pixel radiation sensing element 160 via the buffer area 120, but also can block at least partially the radiation propagating in the substrate 210 towards the active pixel radiation sensing element 400 via the buffer area 120, thereby can reduce the effects of the external radiation on both the black pixel radiation sensing element 160 and the active pixel radiation sensing element 400. In this case, the blocking wall 410 may either contact with the shielding area 140 (similar to the case shown in FIG. 6) or not contact with the shielding area 140.

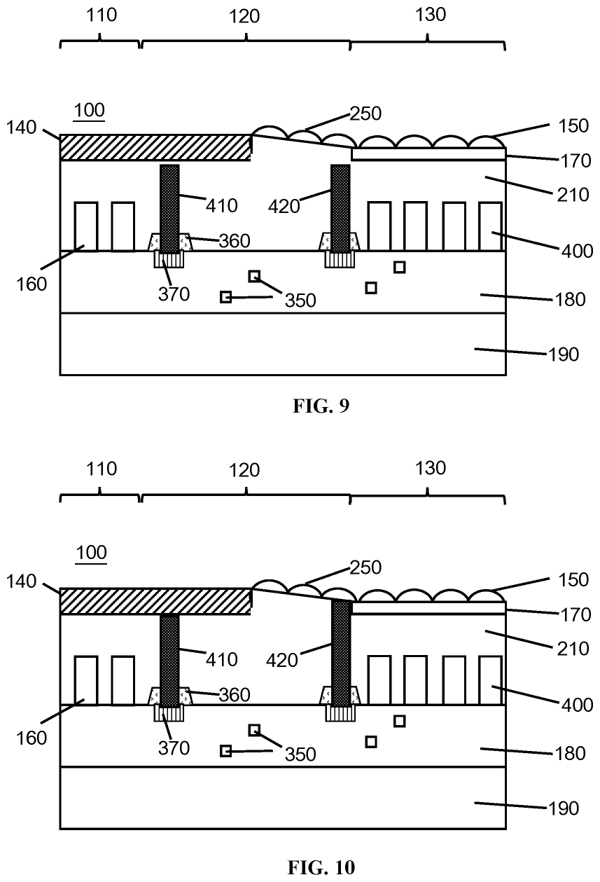

In some embodiments, as shown in FIG. 9, in addition to the blocking wall 410, another blocking wall 420 may be formed in the buffer area 120. In some embodiments, the blocking wall 420 may be formed at a position adjacent to the active pixel area 130 in the buffer area 120, and the blocking wall 410 and the blocking wall 420 are separated from each other. The blocking wall 420 can block at least partially the radiation propagating in the substrate 210 towards the active pixel radiation sensing element 400 via the buffer area 120. The material forming the blocking wall 420 may be the same as or different from the material forming the blocking wall 410. In some embodiments, the material forming the blocking wall 420 may be tungsten.

In FIG. 9, the blocking wall 420 is schematically illustrated as perpendicular to the main surface of the substrate 210. However, the blocking wall 420 may extend obliquely relative to the main surface of the substrate 210 rather than being perpendicular to the main surface of the substrate 210. In some embodiments, in the cross-sectional view of an image sensor, such as the cross-sectional view shown in FIG. 9, the blocking wall 420 may also be in a fold line shape or curved shape or any other suitable shape, provided that the radiation propagating in the substrate 210 towards the active pixel radiation sensing element 400 via the buffer area 120 can be at least partially blocked.

In some embodiments, the blocking wall 410 may run through the entire substrate 210 in a longitudinal direction. In some embodiments, the blocking wall 420 may run through the entire substrate 210 in a longitudinal direction. For example, FIG. 10 shows an example that both the blocking wall 410 and 420 run through the entire substrate 210 in a longitudinal direction.

In some embodiments, the distance between the blocking wall 410 and the black pixel radiation sensing element 160 is at least 1 micron, thereby it can prevent the blocking wall 410 from interfering with the black pixel radiation sensing element 160. In some embodiments, the distance between the blocking wall 420 and the active pixel radiation sensing element 400 is at least 1 micron, thereby it can prevent the blocking wall 420 from interfering with the active pixel radiation sensing element 400.

In some embodiments, the width of the blocking wall 410 is 2 to 4 microns. In some embodiments, the width of the blocking wall 420 is 2 to 4 microns.

In some embodiments, above the active pixel radiation sensing element 400, a color filter 170 for filtering the radiation incident on the image sensor 100 (e.g., light radiation, including but not limited to visible light, infrared ray, ultraviolet ray, X-ray, etc.) and one or more microlenses 150 for converging the radiation to cause the radiation to propagate to the active pixel radiation sensing element 400 may also be provided.

In some embodiments, a pseudo-microlens 250 may also be provided in the buffer area 120. There is no active pixel radiation sensing element below the pseudo-microlens 250, so the pseudo-microlens 250 may not actually participate in the image sensing.

In some embodiments, a dielectric stack 180 may also be provided under the substrate 210. In the dielectric stack 180, a metal interconnection 350 may be formed. In some embodiments, a carrier wafer 190 may also be provided under the dielectric stack 180 to carry the entire image sensor 100.

In some embodiments, a shallow trench isolation (STI) portion 360 enclosing the blocking wall 410 or 420 may be formed at a position near the blocking wall 410 or 420 which is close to the dielectric stack 180. The shallow trench isolation portion 360 may be formed, for example, by silicon dioxide, so as to prevent electrical signal crosstalk between the blocking wall 410 or 420 and the nearby components (e.g., the radiation sensing elements).

In some embodiments, a polycrystalline silicon resistance 370 may also be formed at a position near the blocking wall 410 or 420 in the dielectric stack 180. The polycrystalline silicon resistance 370 can act as a barrier so as to prevent etching into the dielectric stack 180 when etching trenches for the substrate 210 for forming the blocking wall 410 or 420.

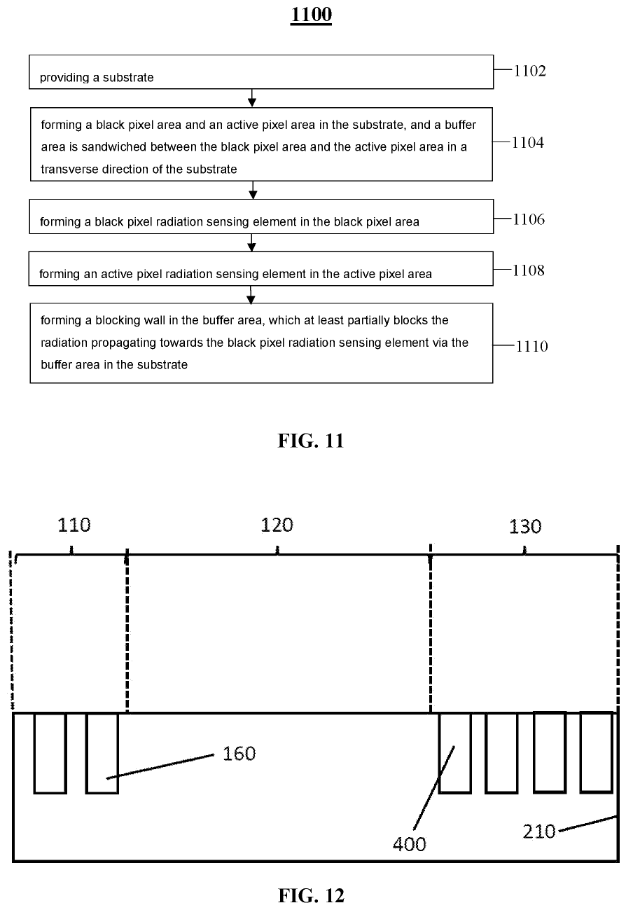

The present disclosure also includes a method 1100 for manufacturing an image sensor 100. FIG. 11 is a flowchart illustrating a manufacturing method 1100 for an image sensor according to some embodiments of the present disclosure. FIGS. 12-17 schematically illustrate a cross-sectional view of an image sensor corresponding to some steps of the method 1100 shown in FIG. 11. The method 1100 will be described below in combination with FIG. 11 and FIGS. 12-17.

In step 1102, a substrate (e.g., the substrate 210 in FIG. 12) is provided. In step 1104, a black pixel area (for example, the black pixel area 110 in FIG. 12) and an active pixel area (for example, the active pixel area 130 in FIG. 12) are formed in the substrate, and a buffer area is sandwiched between the black pixel area and the active pixel area in the transverse direction of the substrate. For example, the black pixel area and active pixel area may be formed by photolithography. In step 1106, one or more black pixel radiation sensing elements (e.g., the black pixel radiation sensing element 160 in FIG. 12) (e.g., optical sensing elements (e.g., photodiodes)) are formed in the black pixel area. In some embodiments, for example, a radiation sensing element may be formed by doping the substrate to form, for example, a PN junction.

In some embodiments, optionally, the method 1100 may also include step 1108. In step 1108, one or more active pixel radiation sensing elements (e.g., the active pixel radiation sensing element 400 in FIG. 12) (e.g., optical sensing elements (e.g., photodiodes) are formed in the active pixel area.

In different embodiments, the provided substrate may either have been thinned or have not been thinned.

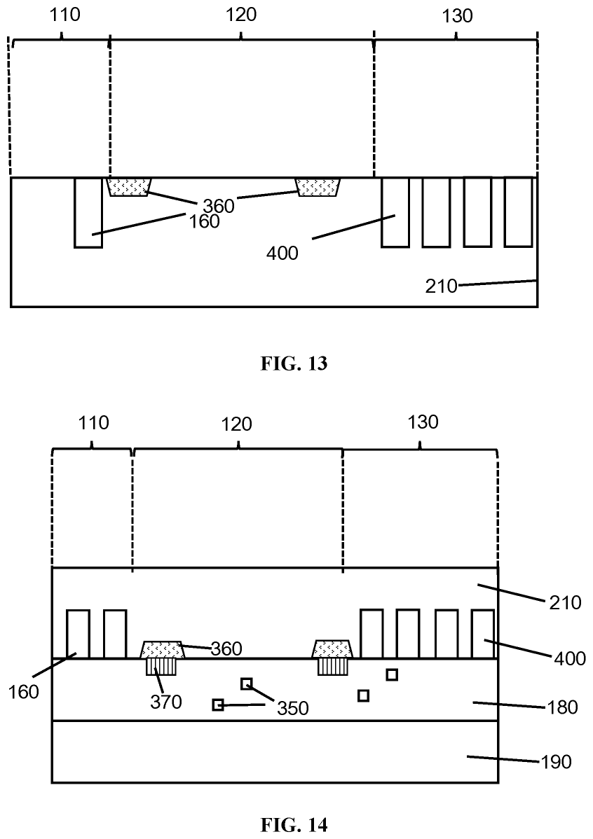

In some embodiments, optionally, the method 1100 may also include forming one or more shallow trench isolation portions (e.g., the shallow trench isolation portions 360 shown in FIG. 13) on the first main surface of the substrate (e.g., the upper surface shown in FIG. 13). In some embodiments, for example, the shallow trench isolation portion is formed by etching a shallow trench on the surface of the substrate using a mask, and then depositing, for example, silicon dioxide (SiO₂) in the shallow trench.

In some embodiments, optionally, the method 1100 may also include bonding the substrate to a dielectric stack (e.g., the dielectric stack 180 shown in FIG. 14). For example, the first main surface of the substrate 210 (for example, the lower surface of the substrate 210 in FIG. 14. Compared with FIG. 13, the substrate 210 in FIG. 14 is flipped by 180 degrees) is bonded with the dielectric stack 180, as shown in FIG. 14. In some embodiments, the dielectric stack 180 is formed by, for example, silicon dioxide. In some embodiments, a metal interconnection 350 is formed in the dielectric stack 180. In some embodiments, a polycrystalline silicon resistance 370 is formed at a position in the dielectric stack 180 which is near the shallow trench isolation portion 360 in the substrate 210. In some embodiments, the polycrystalline silicon resistance 370 is formed by depositing polycrystalline silicon on the dielectric stack 180 and then etching the deposited polycrystalline silicon with a mask.

In some embodiments, optionally, the method 1100 may also include bonding the substrate and the dielectric stack with a carrier wafer. For example, as shown in FIG. 14, the lower surface of the dielectric stack 180 is bonded with the carrier wafer 190.

In step 1110, a blocking wall is formed in the buffer area (for example, the blocking wall 410 shown in FIG. 16), which at least partially blocks the radiation propagating towards the black pixel radiation sensing element via the buffer area in the substrate. The material forming the blocking wall may be opaque material, translucent material or radiation absorbing material. In some embodiments, the opaque material or translucent material may be any suitable material, such as metal, resin, plastics, metallic or non-metallic oxides, graphite, etc., or the combination of these materials. In some embodiments, the radiation absorbing material may be germanium or silicon germanium, for example.

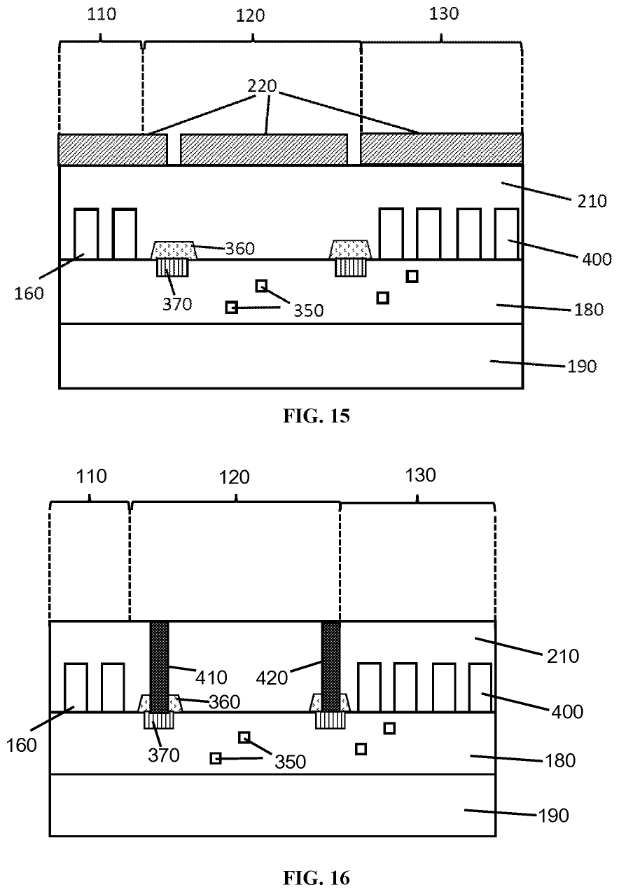

In some embodiments, step 1110 may include: forming a mask 220 (as shown in FIG. 15) on the second main surface of the substrate (e.g., the upper surface of the substrate 210 in FIG. 15) using, for example, a photoresist or a hard mask; etching the substrate to form a trench by using the mask; and filling the trench with opaque materials, translucent materials or radiation absorbing materials so as to form the blocking wall. In some embodiments, the blocking wall is formed by depositing tungsten powder in the trench. In some embodiments, forming the trench includes, for example, forming a back through substrate via (BTSV). In these embodiments, a blocking wall longitudinally passing through the entire substrate 210 (as shown in FIG. 16) may be formed.

In some embodiments, the distance between the blocking wall and the black pixel radiation sensing element is at least 1 micron.

In some embodiments, after the blocking wall is formed, the mask (for example, the mask 220 shown in FIG. 15) can be removed.

In some embodiments, optionally, another blocking wall (for example, the blocking wall 420 shown in FIG. 16) may be formed in the buffer area. The another blocking wall is adjacent to the active pixel area and can at least partially block the radiation propagating towards the active pixel radiation sensing element via the buffer area in the substrate. The method for forming the another blocking wall may be the same as or different from that for forming the blocking wall in step 1110. In some embodiments, the another blocking wall may run through the entire substrate 210 in the longitudinal direction (as shown in FIG. 16).

In some embodiments, the distance between the another blocking wall and the active pixel radiation sensing element is at least 1 micron.

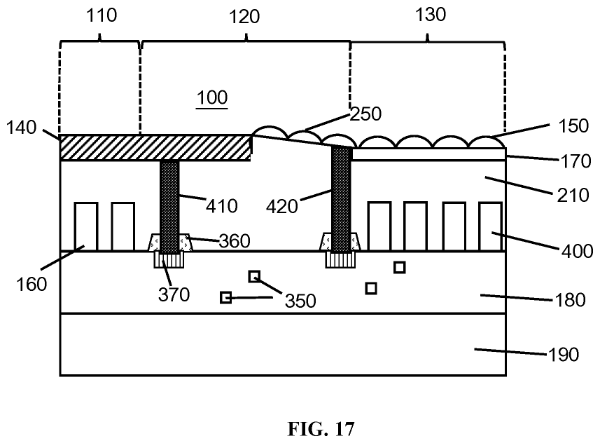

In some embodiments, for example, as shown in FIG. 17, a shielding area 140 may be formed above the black pixel radiation sensing element 160, which at least partially blocks the radiation propagating towards the black pixel radiation sensing element 160 from above the black pixel radiation sensing element 160. In some embodiments, the shielding area 140 may be formed by depositing metal (e.g., aluminium) above the black pixel radiation sensing element 160. In some embodiments, the shielding area 140 covers all the black pixel radiation sensing elements 160 in the transverse direction. In some embodiments, the shielding area 140 extends from the black pixel area 110 to the buffer area 120 in the transverse direction and occupies at least a portion of the buffer area 120. In some embodiments, for example, as shown in FIG. 17, a portion of the blocking wall 410 contacts with the shielding area 140.

In some embodiments, for example, as shown in the above described FIG. 8, the shielding area 140 spans across the entire black pixel area 110 and the entire buffer area 120 in a transverse direction. In some embodiments, as shown in the above described FIG. 8, the blocking wall 410 is adjacent to the active pixel area 130 in the buffer area 120, and the blocking wall 410 can also block at least partially the radiation propagating towards the active pixel radiation sensing element 400 via the buffer area 120 in the substrate 210.

In some embodiments, the widths of the blocking wall 410 and 420 may be 2 to 4 microns.

In some embodiments, the other components of the image sensor are formed in the front end of line (FEOL) and the behind end of line (BEOL). For example, as shown in FIG. 17, a color filter 170 for filtering the radiation incident on the image sensor 100 and one or more microlenses 150 for converging the radiation such that the radiation propagates to the active pixel radiation sensing element 400 may also be formed above the active pixel radiation sensing element 400.

In some embodiments, a pseudo microlens 250 may be formed in the buffer area 120. There is no active pixel radiation sensing element below the pseudo-microlens 250, so the pseudo-microlens 250 may not actually participate in the image sensing.

In some embodiments, the present disclosure also includes an imaging device (not shown), which includes the image sensor 100 as described above or the image sensor 100 manufactured according to the method as described above. The imaging device may also include a lens for converging the external radiation and guiding it to the image sensor 100.

According to some embodiments of the present disclosure, a blocking wall may be formed in the buffer area of the image sensor, which can at least partially block the radiation propagating in the substrate towards the black pixel radiation sensing element via the buffer area, thereby reducing the influence of the stray radiation from the outside of the image sensor on the black pixel radiation sensing element. Thus, it is possible to measure the dark current more accurately. According to some embodiments of the present disclosure, the blocking wall can also at least partially block the radiation propagating in the substrate towards the active pixel radiation sensing element via the buffer area, thereby reducing the influence of the stray radiation from the outside of the image sensor on the active pixel radiation sensing element.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor comprising:
a substrate;
a black pixel area formed in the substrate including a black pixel radiation sensing element;
an active pixel area formed in the substrate; and
a buffer area, wherein the black pixel area and the active pixel area sandwich the buffer area in a transverse direction of the substrate, and a first blocking wall that at least partially blocks radiation propagating towards the black pixel radiation sensing element via the buffer area in the substrate is formed in the buffer area.

2. The image sensor according to claim 1, further comprising:
a shielding area located above the black pixel radiation sensing element, which at least partially blocks the radiation propagating towards the black pixel radiation sensing element from above the black pixel radiation sensing element.

3. The image sensor according to claim 2,
wherein the shielding area extends from the black pixel area to the buffer area and occupies at least a portion of the buffer area; and
a part of the first blocking wall is in contact with the shielding area.

4. The image sensor according to claim 2, wherein the shielding area spans across the entire black pixel area and the entire buffer area in the transverse direction.

5. The image sensor according to claim 4, wherein:
the active pixel area includes an active pixel radiation sensing element,
the first blocking wall is adjacent to the active pixel area in the buffer area, and
the first blocking wall also at least partially blocks the radiation propagating toward the active pixel radiation sensing element via the buffer area in the substrate.

6. The image sensor according to claim 1, wherein:
the first blocking wall runs through the entire substrate in a longitudinal direction.

7. The image sensor according to claim 3, wherein:
the active pixel area includes an active pixel radiation sensing element, and
the image sensor further comprises:
a second blocking wall formed in the buffer area adjacent to the active pixel area, the second blocking wall at least partially blocks the radiation propagating towards the active pixel radiation sensing element via the buffer area in the substrate.

8. The image sensor according to claim 7,
wherein the second blocking wall runs through the entire substrate in a longitudinal direction.

9. The image sensor according to claim 7, wherein:
the distance between the first blocking wall and the black pixel radiation sensing element is at least 1 micron; and
the distance between the second blocking wall and the active pixel radiation sensing element is at least 1 micron.

10. The image sensor according to claim 7,
wherein the widths of the first blocking wall and the second blocking wall are 2 to 4 microns.

11. A method for manufacturing an image sensor comprising:
providing a substrate;
forming a black pixel area and an active pixel area in the substrate, wherein a buffer area is sandwiched between the black pixel area and the active pixel area in a transverse direction of the substrate;
forming a black pixel radiation sensing element in the black pixel area; and
forming a first blocking wall in the buffer area, which at least partially blocks radiation propagating towards the black pixel radiation sensing element via the buffer area in the substrate.

12. The method according to claim 11, further comprising:
forming a shielding area above the black pixel radiation sensing element, which at least partially blocks the radiation propagating towards the black pixel radiation sensing element from above the black pixel radiation sensing element.

13. The method according to claim 12, wherein:
the shielding area extends from the black pixel area to the buffer area and occupies at least a portion of the buffer area; and
a part of the first blocking wall is in contact with the shielding area.

14. The method according to claim 12,
wherein the shielding area spans across the entire black pixel area and the entire buffer area in the transverse direction.

15. The method according to claim 14, further comprising:
forming an active pixel radiation sensing element in the active pixel area,
wherein, the first blocking wall is adjacent to the active pixel area in the buffer area, and
the first blocking wall also at least partially blocks the radiation propagating toward the active pixel radiation sensing element via the buffer area in the substrate.

16. The method according to claim 11,
wherein the first blocking wall runs through the entire substrate in a longitudinal direction.

17. The method according to claim 13, further comprising:
forming an active pixel radiation sensing element in the active pixel area, and
forming a second blocking wall adjacent to the active pixel area in the buffer area, the second blocking wall at least partially blocks the radiation propagating toward the active pixel radiation sensing element via the buffer area in the substrate.

18. The method according to claim 17,
wherein the second blocking wall runs through the entire substrate in the longitudinal direction.

19. The method according to claim 11, forming a first blocking wall in the buffer area comprising:
etching a trench in the buffer area in the substrate using a mask;
forming the first blocking wall by depositing an opaque material or a translucent material or a radiation absorbing material in the trench.

20. An imaging device comprising:
the image sensor according to claim 1; and
a lens for converging the external radiation and guiding it to the image sensor.
